(19) United States
(12) Patent Application Publication
(10) Pub. No.: US 2008/0135891 A1
(43) Pub. Date: Jun. 12, 2008

(54) Transistor Device Formed on a Flexible Substrate Including Anodized Gate Dielectric

(75) Inventors: Ana Claudia Arias, San Carlos, CA (US); Rene Lujan, Sunnyvale, CA (US); Robert Street, Palo Alto, CA (US)

Correspondence Address: JAS IP CONSULTING, 309 2ND STREET, SUITE 8, LOS ALTOS, CA, 94022, US

(73) Assignee: PALO ALTO RESEARCH CENTER, INCORPORATED, Palo Alto, CA (US)

(21) Appl. No.: 11/608,577

(22) Filed: Dec. 8, 2006

(51) Int. Cl. H01L 29/76

(52) U.S. Cl. 257/288

(57) ABSTRACT

A transistor device is formed on a flexible substrate such that device processing remains at a low temperature. A first gate dielectric layer is formed over gate metal by annodization, eliminating relatively high-temperature dielectric deposition processes and difficulties with in-process substrate deformation. A second gate dielectric layer may optionally be provided over the first in order to provide an improved dielectric/semiconductor interface. A high performance pixel, and process for producing same, may thus be provided on a flexible substrate.

### STATEMENT REGARDING FEDERALLY SPONSORED RESEARCH AND DEVELOPMENT

The U.S. Government has a fully paid-up license in this invention and the right in limited circumstances to require the patent owner to license others on reasonable terms as provided for by the terms of contract number 70NANB3H3029 awarded by the Department of Commerce, Advanced Technology Program.

### BACKGROUND OF THE INVENTION

1. Field of the Invention

The present invention relates to transistor devices formed on flexible substrates, and more specifically to a device including a first dielectric layer formed by anodizing a patterned metal, with an optional subsequently formed second dielectric layer thereover.

2. Description of the Prior Art

There exists today many types and techniques for fabricating flat-panel display devices, for example of the type used as a computer display, television monitor, etc. For the purposes herein, the term “display” will generically encompass all such devices. Displays may be comprised of active matrix or passive matrix elements, and may be either transmissive or reflective. At the core of each picture element, or pixel, of these displays is most commonly a thin-film transistor (TFT). Transmissive and reflective displays typically include polysilicon or amorphous silicon thin-film transistors. Organic semiconductor thin film transistors are also becoming increasingly important.

Displays are generally comprised of at least a substrate and a backplane. The backplane forms the electrical interconnection of the display and typically comprises electrodes, capacitors, and transistors for addressing the individual pixels making up the display. The substrate forms the structure carrying the backplane, and is often (but not always) the structure upon which the backplane is formed. Substrates may be divided into classes of either rigid or flexible. As their classification suggests, rigid substrates are not intended to be bent, flexed, or deformed. In many applications, rigidity is desirable, for example in computer displays (desktop and portable), television monitors, cell phone and PDA displays, etc. However, in certain applications a flexible display, i.e., one able to bend, fold, roll, etc., is desirable. In these applications, the substrate and backplane must be sufficiently flexible to accommodate.

Formation of backplanes on rigid substrates is better known and more common today than is forming backplanes on flexible substrates. Many of the current limitations on using flexible substrates originate with the process requirements and structures of the devices, such as the thin-film transistors (TFTs), which comprise the backplane.

As an example, a schematic illustration of the backplane circuitry 10 of a typical prior art TFT display array is provided in FIG. 1. Two pixels 6, 8 are described. Electrical interconnections 12 and 14 form control lines, which are coupled to the gate electrodes 16, 18 of TFTs 20, 22. Data line 24 is connected to the source electrodes 28, 30 of TFTs 20, 22. Data drivers (not shown) connected to data lines 24, 26 supply pixel voltages which are applied to the pixel electrodes. The drain electrodes 32, 34 of TFTs 20, 22 are coupled to pixel electrodes 40, 42. It will be understood that a typical backplane includes thousands to millions of pixels identical to those described here.

In one typical example, backplane 10 may be formed by a series of depositions and etchings on a rigid substrate (e.g., glass). An active medium (e.g., a liquid crystal, not shown) is deposited at least over the pixel electrodes 40, 42. Optical properties of localized regions of the active medium may then be altered in response to voltages or currents produced by the pixel electrodes, when polarizing films are placed on either side of the display. For example, the active medium at a given pixel electrode may become transparent or opaque in response to a voltage applied to the pixel electrode, thereby forming the appearance of a rectangle, dot, etc. at that pixel. The application of a color filter or filter grid (not shown) over the active material can provide the appearance of a colored rectangle, dot, etc. Images may then be formed on the array by individually addressing the TFTs in each of the plurality of pixels forming the backplane matrix.

FIG. 2 is a cut-away elevation illustrating the typical elements of a TFT stack 44 according to the prior art. At the base of stack 44 is substrate 46, on which is formed gate metal 48. Substrate 46 is typically a rigid, transparent material such as glass. However, as will be discussed further below, flexible substrate materials, such as plastics, are becoming increasingly important. Dielectric layer 50 is formed over gate metal 48 to electrically insulate the gate electrode and gate line from subsequent layers. Source electrode 52 and drain electrode 54 are formed partially overlapping the gate electrode 48, and a semiconductor active region 56 is formed in electrical contact with and between the source and drain electrodes 52, 54. Various insulation layers (e.g., 58) and contact layers (e.g., 60) are formed thereover.

Of particular relevance to the present invention, the aforementioned dielectric layer 50 is typically formed by a relatively high temperature process, such as chemical vapor deposition (CVD). This high temperature process is most often compatible with typical rigid substrates. There is, however, a desire to use flexible substrates in order to produce flexible displays, sensor arrays, etc. Unfortunately, the material from which the flexible substrates are formed cannot withstand typical high temperature deposition processes. For example, above about 150° C., the typical flexible substrate material deforms. Furthermore, typical dielectric layers formed by higher temperature processes exhibit high intrinsic mechanical stress, which deforms the substrate and makes alignment for subsequent processing steps difficult.

There have been efforts to develop deposition processes compatible with flexible substrates, but such efforts have heretofore failed to produce effective results. For example, low temperature deposition processes have been developed, for example for forming the dielectric layer. However, dielectric layers formed by these processes have typically been of poor quality and exhibit poor performance, for example due to a high density of pin holes, excessive leakage currents, etc. Efforts to address the quality of the dielectric layers, for example by forming a relatively dense or thick dielectric layer have proved inadequate since as the density or thickness of the dielectric layer increases, so does the mechanical stress within the layer, resulting in deformation of the substrate and difficulty with alignment for subsequent processing steps. Furthermore, obtaining proper operating capacitance of the gate dielectric limits the thickness of the dielectric layer.

Another impediment associated with using a flexible substrate is surface roughness. Flexible substrates have a relatively higher surface roughness that traditional non-flexible substrates such as glass. Surface roughness is important when depositing organic semiconductors, as the surface roughness affects the organization of the polymer chains which determine the mobility of the material. Forming an organic semiconductor on a rough base results in ineffective polymer self-organization, and hence poor mobility and degraded device performance.

Efforts to address the roughness issue have again focused on forming a relatively thick dielectric layer. However, such a thick dielectric introduces the aforementioned stress and thickness-based capacitance issues, as well as so-called step coverage problems (e.g., non-uniform layer thicknesses at top, side, and corner of gate electrode), and the associated difficulties with controlling parasitic capacitances and shorts.

### SUMMARY OF THE INVENTION

Accordingly, the present invention is directed to a method of forming, and structure so formed, operable as a thin film transistor. More particularly, the present invention is directed to a gate dielectric formed by a low temperature (e.g., at or below 150° C.) process. The method, and the structure so produced, is compatible with flexible substrates, enabling the production of, for example, flexible display and sensor arrays. A novel flexible display and a novel flexible sensor array are thus enabled.

According to one aspect of the invention the method begins with the deposition of a gate metal on a flexible substrate. The gate metal is patterned to form transistor gate structures and gate lines. The gate metal is then anodized to form a first dielectric layer which is self-patterning with the patterned gate metal. A second dielectric layer is then formed or deposited by a low temperature process over the first dielectric layer. The second dielectric layer is then patterned such that it is roughly the width of the anodized first dielectric layer. Importantly, all steps to this point in the process are performed at a low temperature, preferably at or below 150° C. The dielectric material therefore resides solely over the gate metal, providing a structure with minimized dielectric-induced intrinsic stress, and hence minimized deformation of the substrate.

According to a second aspect of the invention, the second dielectric layer is deposited such that a relatively smooth, uniform top surface is presented on which a semiconductor layer can subsequently be deposited. The smooth, uniform top surface allows an organic semiconductor material to self-organize, thereby providing desired electron/hole mobility in the layer of that material.

The above is a summary of a number of the unique aspects, features, and advantages of the present invention. However, this summary is not exhaustive. And while an example of the present invention has been described in terms of a display device, an array of other assemblies such as radiation detectors (x-ray, radar, etc.), micro-electro-mechanical structural elements (MEMS), flexible antennas or, generally, an assembly of sensors or actuators or an assembly of circuit elements may similarly be produced. Thus, these and other aspects, features, and advantages of the present invention will become more apparent from the following detailed description and the appended drawings, when considered in light of the claims provided herein.

### BRIEF DESCRIPTION OF THE DRAWINGS

In the drawings appended hereto like reference numerals denote like elements between the various drawings. While illustrative, the drawings are not drawn to scale. In the drawings:

FIG. 1 is an illustration of a portion of a pixel array according to the prior art.

FIG. 2 is a cross sectional view of a TFT structure according to the prior art.

FIGS. 3a-3f are cut-away side views of a TFT device during manufacture according to one embodiment of the present invention.

FIGS. 4a-4b are optical micrographs of a portion of a TFT fabricated according to the embodiment of the present invention illustrated in FIGS. 3a-3f.

FIG. 5 is a graph illustrating the relationship between dielectric layer thickness and cut-off voltage according to the first embodiment of the present invention.

FIG. 6 is a graph illustrating the relationship between dielectric layer capacitance and cut-off voltage according to the first embodiment of the present invention.

FIG. 7 is a graph illustrating the transfer characteristics of a TFT according to the first embodiment of the present invention.

FIGS. 8-16 are cut-away side views of a TFT device during manufacture according to a second embodiment of the present invention.

FIG. 17 is an optical micrograph of a portion of an array of pixels, including TFTs, manufactured according to the embodiment of the present invention illustrated in FIGS. 8-16.

FIGS. 18a and 18b are graphs of the transfer and output characteristics, respectively, of a TFT according to the second embodiment of the present invention.

FIGS. 19-27 are cut-away side views of a TFT device during manufacture according to a third embodiment of the present invention.

FIGS. 28a-28c are optical micrographs of portions of an array of pixels, manufactured according to the embodiment of the present invention illustrated in FIGS. 19-27.

FIGS. 29a and 29b are graphs of the transfer and output characteristics, respectively, of a TFT according to the third embodiment of the present invention.

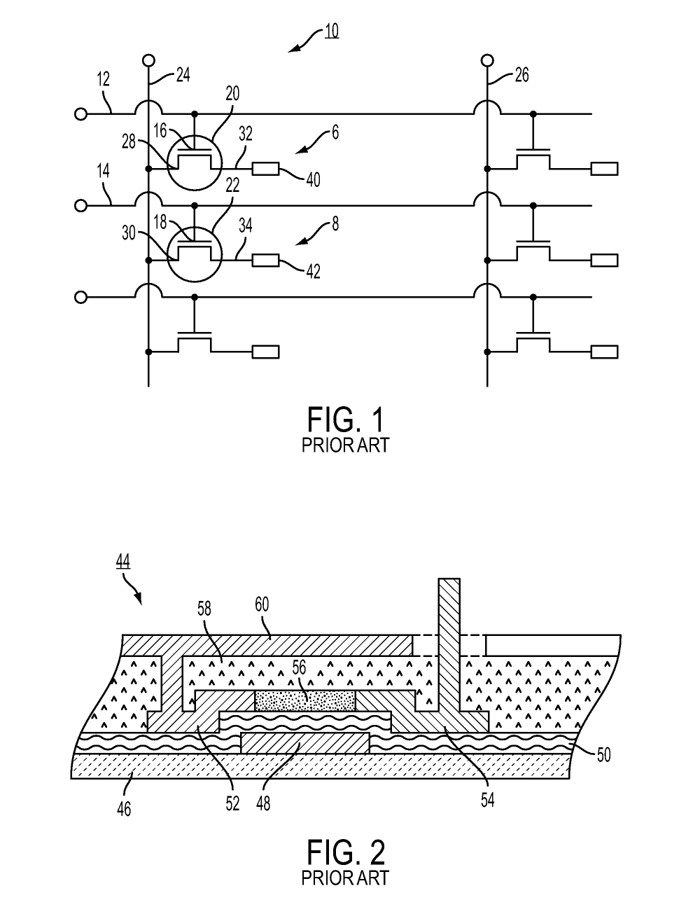

### DETAILED DESCRIPTION OF THE INVENTION

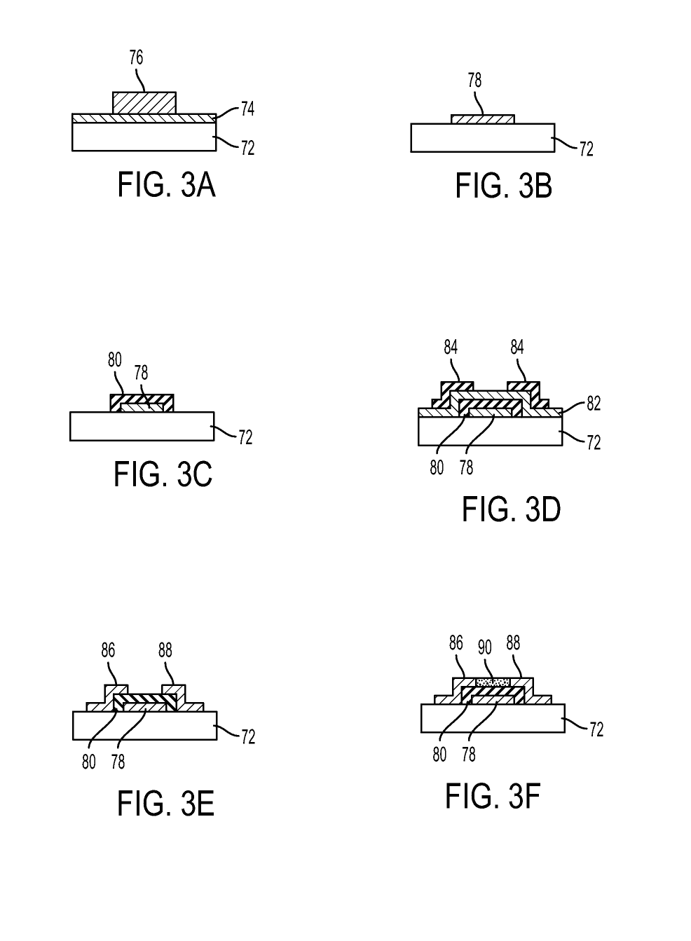

According to a first embodiment of the present invention, illustrated in FIGS. 3a-3f, a TFT structure stack 70 is formed over a flexible substrate 72. Flexible substrate 72 may be a plastic film such as polyethylene naphthalate (PEN) polyethylene teraphlalate (PET), or a metal foil such as steel or even a thin glass sheet. Initially, a layer 74 of tantalum is deposited over substrate 72 by sputtering or thermal evaporation. Mask 76 is then formed over tantalum layer 74, for example by conventional photolithography or print patterning techniques such as those taught by Wong et al. in U.S. non-provisional patent application Ser. No. 11/193,847 (referred to as Wong et.), and the references cited therein (including U.S. Pat. Nos. 6,742,884 and 6,872,320), each of which being incorporated by reference herein. The structure is then etched, using mask 76 to protect a region of layer 74 thereunder, to thereby define a tantalum gate structure 78, as shown in FIG. 3b.

As an alternative to the process so far, a layer of aluminum may initially be deposited over substrate 72, and patterned to form a gate sub-structure. The aforementioned layer 74 of tantalum is then deposited over the aluminum gate sub-structure. The tantalum layer is patterned such that it encloses the aluminum sub-structure over substrate 74. While not required by the present invention, this tantalum/aluminum gate structure provides increased conductivity for gate lines and similar structures, if required.

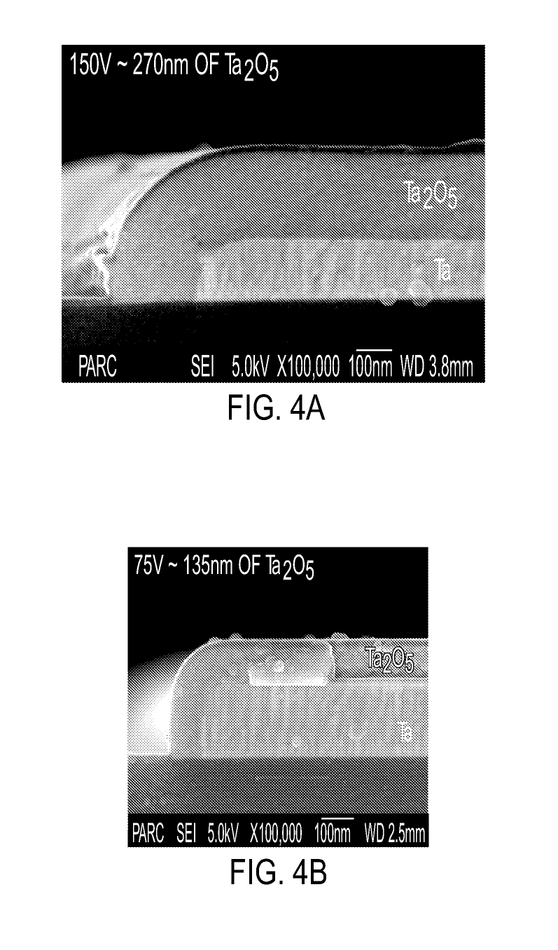

With reference now to FIG. 3c, the in-process structure is then anodized to form a dielectric layer 80 of Ta₂O₅ over tantalum gate structure 76. The conditions and parameters for anodizing, and the control over the thickness of Ta₂O₅ dielectric layer 80 formed thereby, are discussed further below with regard to FIGS. 4a-4b. However, it is a result of this process that tantalum gate structure 78 is fully covered by a uniformly thick Ta₂O₅ dielectric layer 80. One advantage of the annodization process for forming the dielectric layer 80 is that coverage of gate structure 76 is of uniform thickness, thus providing improved uniform capacitance as compared to other techniques of forming the dielectric layer. The anodized Ta₂O₅ layer 80 also has rounded edges providing good step coverage for subsequent layers. Furthermore, the anodization process provides uniform density coverage, reducing the pin-hole count as compared to solution process dielectrics (organic dielectrics) for large area arrays.

The source/drain metal layer 82 may next be deposited over Ta₂O₅ dielectric layer 80 and the exposed portions of substrate 27, as illustrated in FIG. 3d. Source/drain metal layer 82 is typically composed of gold with a chromium adhesion layer or some another suitable metal and deposited by sputtering or thermal evaporation to a thickness of approximately 20-100 nm. Source/drain masking structures 84 are next formed over layer 82, again for example by conventional photolithography or print patterning techniques such as those taught by Wong et al.

The structure formed so far is then subjected to an etch which removes portions of the source/drain metal layer 82 exposed by masking structures 84, leaving source electrode 86 and drain electrode 88. Furthermore, Ta₂O₅ dielectric layer 80 is resistant to the etching performed, and thus remains intact even after the etching has removed that portion of the source/drain metal layer 82 previously disposed thereover. Conventional metal etching chemicals can be used. The structure at this stage appears as shown in FIG. 3e.

The final step illustrated in this embodiment of the present invention is shown in FIG. 3f. At this stage in the method of manufacturing the TFT, a polymer semiconducting material 90 such as a polythiophene or any other suitable polymer is deposited in the region between source electrode 86 and drain electrode 88. This deposition may be by spin coating, print patterning, drop casting, or other similar technique known in the art capable of precisely depositing material within the context of solid state device fabrication. Other semiconductors that could be used include zinc oxide deposited by sputtering, organic semiconductors such as pentacene deposited by thermal evaporation, and other related materials. For some semiconducting materials it may be preferred to deposit and pattern the semiconductor before depositing and patterning the source and drain contacts

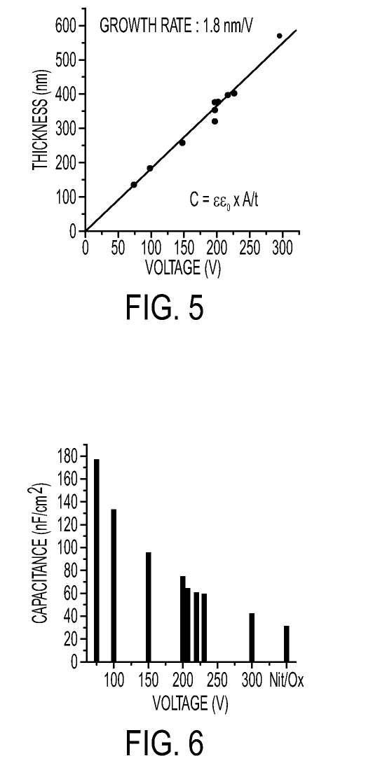

There is a certain degree of control over the thickness of Ta₂O₅ dielectric layer 80 permitted in the aforementioned anodizing of tantalum gate structure 78. For example, according to one embodiment of the present invention, the anodizing is performed at room temperature, and at a rate of approximately 18 Å/volts, consuming approximately 1 nm of tantalum for each 2 nm of Ta₂O₅. Using a limiting voltage of approximately 150 volts produces a 270 nm thick layer of Ta₂O₅, as illustrated in FIG. 4a, while a limiting voltage of approximately 75 volts produces a 135 nm thick layer, as illustrated in FIG. 4b. FIG. 5 is a graph of limiting voltage versus thickness of the Ta₂O₅ dielectric layer, and FIG. 6 is a graph of the limiting voltage versus capacitance of the resulting Ta₂O₅ dielectric layer.

It will be noted from FIGS. 4a and 4b that the Ta₂O₅ layer 80 relatively uniformly covers tantalum gate structure 78, including a relatively uniform thickness at the transition from the upper surface to the side surface of gate structure 78. In this way, the present invention is able to address the previously discussed step coverage problem associate with the prior art.

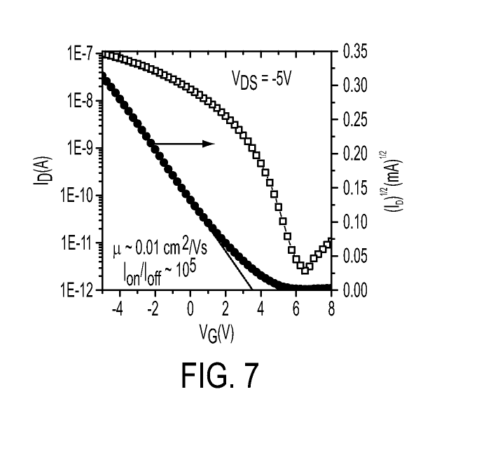

FIG. 7 is an illustration of the TFT device characteristics for a device fabricated according to the process shown in and described with regard to FIG. 3. The operating voltages are controlled by the capacitance, which can be tuned by the limiting voltage during annodization. As illustrated in FIG. 7, the device operates effectively as a TFT. The semiconducting polymer used in this sample was a polythiophene derivative.

Finally, in addition to the formation of individual TFTs, the gate dielectric according to the present invention is also used to electrically isolate the gate and data metal lines in an array of interconnected TFTs of the type described above. It is important that the gate and data lines do not short where they overlap, and by using the gate dielectric for this purpose, no separate additional fabrication steps are required to electrically isolate the lines. Thus as will be appreciated by one skilled in the art, the approach described above can also be applied to electrically isolate overlapping metal address lines.

It will be appreciated from the foregoing that Ta₂O₅ dielectric layer 80 is formed only over tantalum gate structure 78. This should be contrasted with the prior art, in which dielectric material is typically deposited as a continuous film over the entire substrate and intermediate structures formed thereon. Continuous films of sputtered or PECVD material typically have a large mechanical stress arising both from the intrinsic structure of the film and the different thermal expansion compared to the substrate. The stress in such a continuous film tends to deform a plastic substrate because it is a soft material with a low elastic modulus, which renders the alignment of subsequent layers of the device difficult if not impossible. The selective formation of the Ta₂O₅ dielectric layer 80 according to the present invention greatly reduces the intrinsic stress because less of the surface is covered with material, enabling accurate registration following the formation of the dielectric layer.

Furthermore, typical prior art high performance patterned dielectric layers are obtained by using high temperature processing (e.g., above 160° C.) and low particle count clean rooms. As previously mentioned, these high temperature processes are incompatible with materials used for flexible substrates. By substituting printing technology in place of PECVD, strictly low temperature process are employed. As an added benefit, the requirement of an ultra-clean processing environment is eased by the use of printing technology for pattern fabrication.

As previously mentioned, typical flexible substrates present a rougher surface on which materials are deposited as compared to corresponding rigid substrates such as glass. This surface roughness is essentially replicated by the various layers deposited over the substrate, and in particular by the dielectric layer. While some of this surface roughness can be reduced by forming a thick dielectric layer, as previously mentioned, strain and capacitance concerns limit the thickness of the dielectric layer. The surface roughness presented by the layer immediately below the semiconductor layer has an impact on the performance characteristics (e.g., electron/hole mobility) of the semiconductor layer. It is therefore desirable to provide a mechanism for reducing roughness of the surface upon which the semiconductor material is formed.

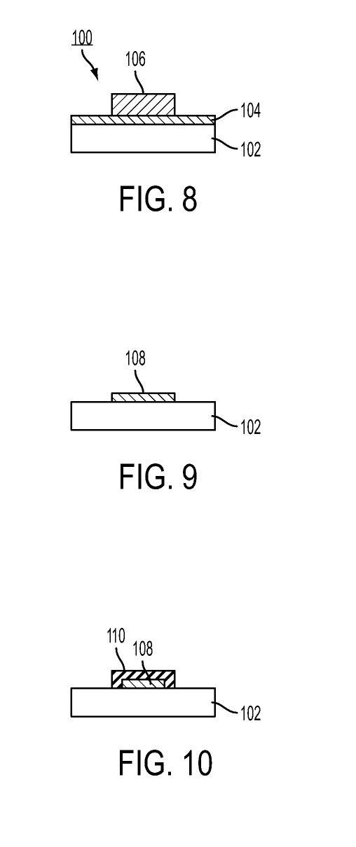

Accordingly, pursuant to a second embodiment of the present invention, a second dielectric layer is formed over the Ta₂O₅ dielectric layer of the prior embodiment. With reference to FIGS. 8a-8g, the process for forming such a structure is shown. With reference first to FIG. 8, a TFT structure stack 100 is formed over a flexible substrate 102. Flexible substrate 102 may be a plastic film or other material as discussed above. A layer 104 of tantalum is deposited over substrate 102. Mask 106 is then formed over tantalum layer 104, for example by a print patterning technique. The structure is then etched, using mask 106 to protect the region of layer 104 thereunder, to thereby define a tantalum gate structure 108, as shown in FIG. 9. The aforementioned aluminum/tantalum combination may also be employed in the present embodiment, if required.

With reference now to FIG. 10, the in-process structure is then anodized to form a dielectric layer 110 of Ta₂O₅ over tantalum gate structure 108. The thickness of Ta₂O₅ dielectric layer 110 may be controlled via the limiting voltage during annodization, which in turn controls the capacitance and hence operating voltage of the TFT. It will again be noted that a result of this process is that tantalum gate structure 108 is fully covered by a uniformly thick Ta₂O₅ dielectric layer 110.

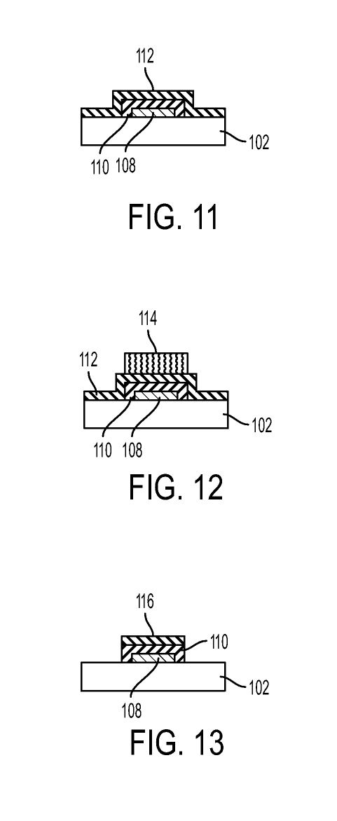

In order to mitigate adverse effects of the relatively rough surface presented by the substrate and transmitted by the various layers formed thereover, according to this embodiment, a second dielectric layer 112 is next applied over Ta₂O₅ layer 110, as shown in FIG. 11. The material comprising second dielectric layer 112 will depend upon the semiconductor material to be used, the process employed for deposition, the desired thickness of that layer, the electrical characteristics (e.g., capacitance) desired, etc. Second dielectric layer 112 may be composed of an inorganic material, such as silicon nitride or oxide, or an organic material, such as poly 4-vinyl phenol (PVP) or other polymers, or a self-assembled monolayer octadecyltrichlorosilane The method of deposition may be any convenient low-temperature (e.g., below about 160° C.) method such as PECVD, sputtering, spin coating, jet printing, etc. As will be seen, the choice of this second dielectric layer material will determine the material interface between the dielectric and the semiconductor material. Therefore, a proper selection of material for this layer will provide control over both the physical characteristics of the structure and the electrical characteristics of the resulting TFT.

Continuous layers formed over a substrate contribute to mechanical stress within the formed structure. This stress is easily capable of shrinking or expanding a flexible substrate. Even a very small change in dimension (known as run out) affects the alignment of the structures, precluding further manufacturing steps. An advantage of the first embodiment described above is that a minimum amount of material remains on the substrate surface. This means that the stress and run-out is reduced, and in-process deformation of the substrate can be eliminated. With a similar goal in mind, according to this second embodiment, an optional step of masking and removing sections of the second dielectric layer 112 may be performed as illustrated in FIG. 12. Mask 114 is formed on the surface of layer 112, generally overlying Ta₂O₅ layer 110 and gate structure 108, for example by print patterning. This is illustrated in FIG. 12. Etching may then be performed to remove exposed portions of layer 112 and to form second dielectric island 116. With the mask 114 removed, a structure as illustrated in FIG. 13 is obtained.

In this second embodiment, the anodized dielectric (Ta₂O₅ layer 112) allows for patterning of the second dielectric layer 112 without causing shunts in areas of metal overlap. The removal of the excess second dielectric layer 112 then further reduces the intrinsic stress within the built-up structure, addressing the concerns about run-out. However, while the remainder of the description of this embodiment will show second dielectric layer 112 etched to form second dielectric island 116, it will be appreciated that this etching is optional, and that the balance of the description may apply equally to a device with second dielectric layer 112 unetched.

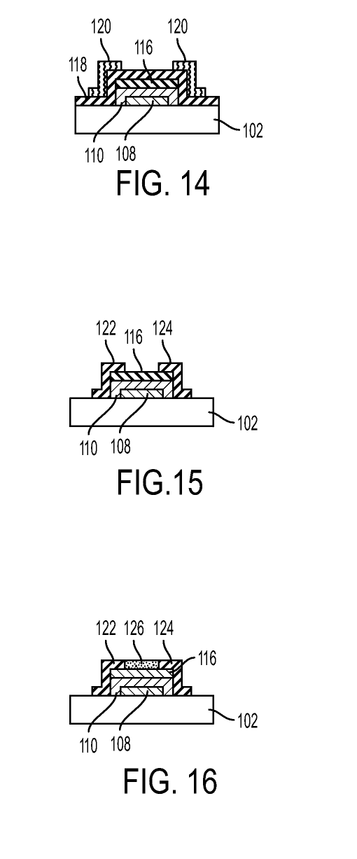

The source/drain metal layer 118 may next be deposited over the structure, as illustrated in FIG. 14. Source/drain metal layer 118 is again typically composed of gold with a chromium adhesion layer and deposited by sputtering or thermal evaporation to a thickness of approximately 20-100 nm. Source/drain masking structures 120 are next formed over layer 118, again for example by print patterning techniques.

The structure formed so far is then etched to remove portions of the source/drain metal layer 118 exposed by masking structures 120, leaving source electrode 122 and drain electrode 124. The structure at this stage appears as shown in FIG. 15.

The final step illustrated in this embodiment of the present invention is shown in FIG. 16. At this stage in the method of manufacturing the TFT, a polymer semiconducting material 126 such as a polythiophene or any other suitable polymer is deposited in the region between source electrode 122 and drain electrode 124. This deposition may be by spin coating, print patterning, drop casting, or other similar technique known in the art capable of precisely depositing material within the context of solid state device fabrication.

Another advantage of the present embodiment is that a pixel storage capacitor associate with the TFT for each pixel maybe formed for example of Ta₂O₅ by anodizing together with the anodizing of the TFT elements previously described. The TFT, which includes the second dielectric material, can then be manufactured with a lower parasitic capacitance for higher device performance. This allows for the formation of physically smaller storage capacitors on pixel arrays with desired higher aperture ratios.

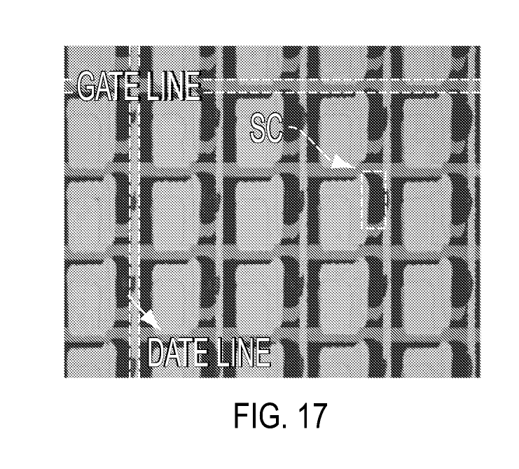

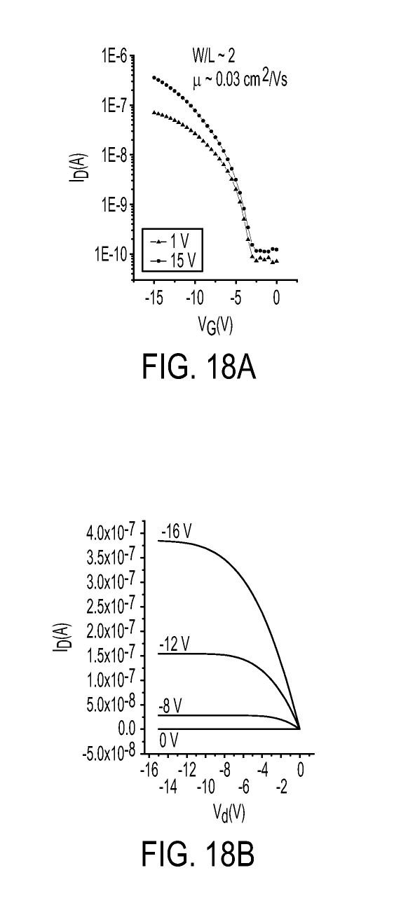

We have fabricated polymer-based TFTs using the aforementioned process. FIG. 17 is a optical micrograph of a section of such a structure, 180 pixels×180 pixels in size. For this sample, the anodized Ta₂O₅ dielectric layer was 90 nm thick, with a 30 nm thick second dielectric of SiO2 deposited at 120° C. The semiconductor material was a polythiophene derivative, of the type used in the first example described above. The transfer and device output characteristics are shown in FIGS. 18a and 18b. It will be noted that use of the second dielectric provides device performance benefits. Based upon the improved gate dielectric/semiconductor interface, parameters such as electron/hole mobility and bias stress are optimized.

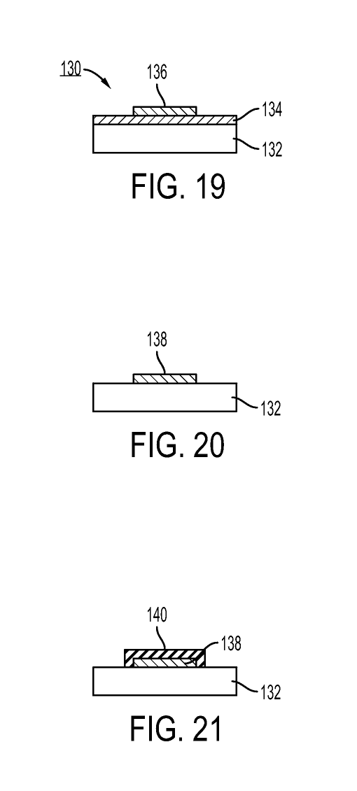

According to a third embodiment of the present invention, an amorphous silicon based TFT is constructed incorporating the aforementioned dual dielectric structure. The steps of a process according to this embodiment is shown in FIGS. 19-27. The process up to a point is similar to that described above for the first and second embodiments. As shown in FIG. 19, a TFT structure stack 130 is formed over a flexible substrate 132. A layer 134 of tantalum is deposited over substrate 132, and mask 136 is then formed over the tantalum layer 134, for example by a print patterning technique. The structure is then etched, using mask 136 to protect the region of layer 134 thereunder. A tantalum gate structure 138 is formed, as shown in FIG. 20 (the aforementioned aluminum/tantalum combination may also be employed in the present embodiment, if required). As shown in FIG. 21, the structure is then anodized to form a dielectric layer 140 of Ta₂O₅ over tantalum gate structure 138, whose thickness is controlled via the limiting voltage during annodization.

At this point, a second dielectric layer 142 is next applied over Ta₂O₅ layer 140. The material comprising second dielectric layer 142 will depend upon the semiconductor material used, the process employed for deposition, the desired thickness of that layer, the electrical characteristics (e.g., capacitance) desired, etc. According to one example, the second dielectric layer 142 comprises PECVD deposited Si₃N₄, SiO₂ or related compositions.

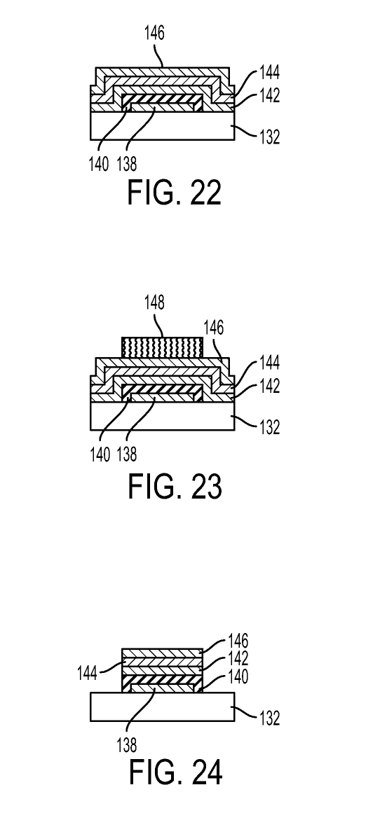

With reference now to FIG. 22, a semiconductor layer 144 of amorphous silicon (a-Si) is deposited over the structure by low-temperature means well known in the art. A highly doped amorphous silicon N+ source/drain contact layer 146 is next deposited over the structure.

In order to alleviate the intrinsic stresses developed by the continuous coverage of second dielectric layer 142, semiconductor layer 144, and N+ layer 146, the optional step of masking and removing sections of these layers may be performed as illustrated in FIG. 23. Mask 148 is formed on the surface of layer 146, generally overlying Ta₂O₅ layer 140 and gate structure 138, for example by print patterning. Etching may then be performed to remove exposed portions of layers 142, 144, and 146, yielding the device illustrated in FIG. 24.

In the description associated with FIGS. 14 through 16, it was assumed that the optional step of etching the continuous layers such that the layer coverage over the substrate was minimized was performed. Similarly, the step of etching the continuous layers such that the layer coverage over the substrate is minimized is also optional for this third embodiment. However, for the following description we will assume that this optional etching has not been performed, with it being understood that similar steps may be performed and results obtained with or without this optional etching.

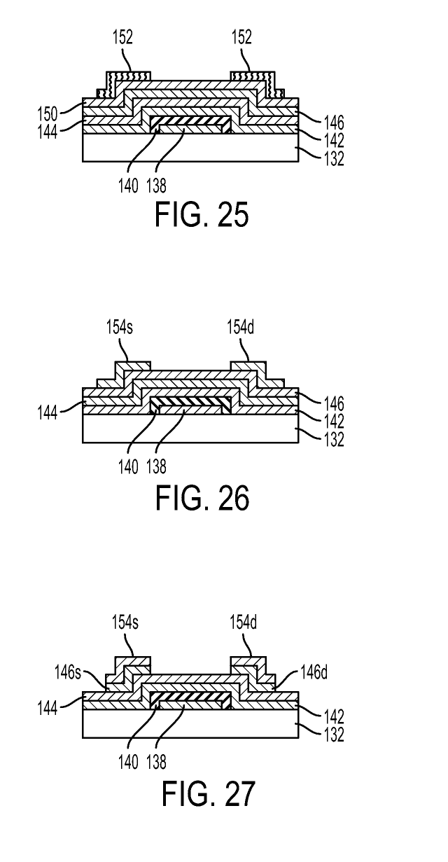

With reference next to FIG. 25, source/drain electrode metal layer 150 is formed over layer 146, and source/drain masking structures 152 are formed over layer 150, again for example by conventional photolithography of print patterning techniques such as those taught by Wong et al. The source/drain metal may be Cr, TiW, Al or another convenient metal. The structure is then etched to remove portions of the source/drain electrode metal layer 150 exposed by masking structures 152, leaving patterned source electrode 154s and drain electrode 154d, as shown in FIG. 26. Source and drain electrodes 154s, 154d may then be used as masks to etch the N+ layer 146 to yield the final structure illustrated in FIG. 27.

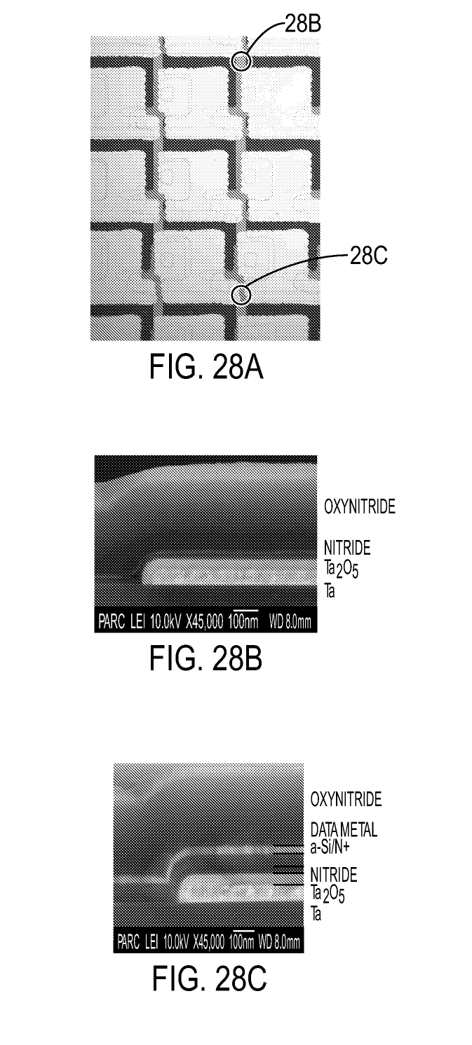

A device according to this third embodiment was built and tested. FIGS. 28a-28c are optical micrographs of a number of pixels from such an array. FIG. 28a illustrates a number of complete pixels, each pixel including a TFT, capacitor, and contact pad. FIG. 28b is a cross section of a TFT, illustrating the coverage of gate dielectric over gate metal. FIG. 28c is a cross section of the overlap of the Ta gate metal line and data metal line, with insulation provided by the Ta₂O₅ product of anodizing the Ta data metal. As can be seen the present invention provides excellent step coverage.

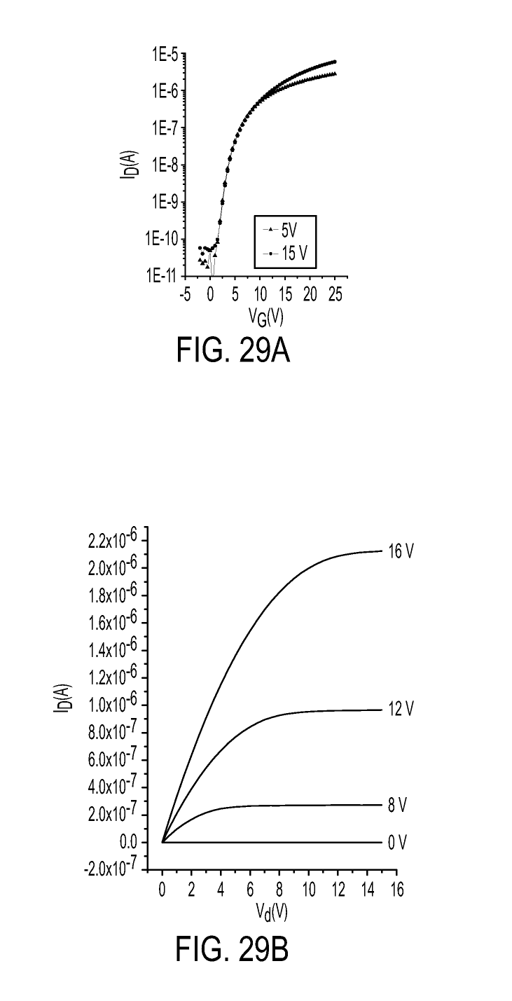

Performance of the device according to this third embodiment was measured, and the results are shown in FIGS. 29a and 29b. It will be noted that in the case of a-Si, as with the polymer-based TFTs, use of the second dielectric provides device performance benefits. Based upon the improved gate dielectric/semiconductor interface, parameters such as electron/hole mobility and bias stress are optimized to obtain performance equivalent to high-temperature devices, yet on flexible substrates. Again, any layer material not over or associate with the formed TFT can be removed to reduce intrinsic stress (but it is noted that techniques exist for depositing low stress source/drain metal layers, especially as compared to layers deposited by PECVD).

While a plurality of preferred exemplary embodiments have been presented in the foregoing detailed description, it should be understood that a vast number of variations exist, such as different materials and stack combinations, and these preferred exemplary embodiments are merely representative examples, and are not intended to limit the scope, applicability or configuration of the invention in any way. In addition, the foregoing examples have focused on the TFTs and pixels, but these elements may form parts of a wide variety of devices, from LCDs, electrophoretic displays, and the like, to sensors of a wide variety. Accordingly, the foregoing detailed description provides those of ordinary skill in the art with a convenient guide for implementation of the invention, and contemplates that various changes in the functions and arrangements of the described embodiments may be made without departing from the spirit and scope of the invention defined by the claims thereto.

What is claimed is:

1. A transistor device, comprising:
a flexible substrate;
patterned gate metal forming a gate and a portion of a gate line of the transistor device;
a first gate dielectric layer comprising an anodized layer substantially covering only top and side surfaces of said gate metal, such that said first gate dielectric layer is minimally disposed over regions of said flexible substrate not also covered by said gate metal;
source and drain contacts disposed at least partially over said first gate dielectric layer; and
a thin film semiconductor material disposed at least between and in physical and electric contact with said source and drain contacts.

2. The transistor device of claim 1, further comprising a second gate dielectric layer disposed substantially over a top surface of said first gate dielectric layer, such that said second gate dielectric layer is minimally disposed over regions of said flexible substrate not also covered by said first gate dielectric and said gate metal.

3. The transistor device of claim 2, wherein said source and drain contacts and said polymer-based semiconductor material are at least partially in physical contact with said second gate dielectric layer.

4. The transistor device of claim 1, wherein said patterned gate metal comprises tantalum, and said first gate dielectric layer comprises Ta₂O₅.

5. The transistor device of claim 2, wherein said patterned gate metal comprises tantalum, said first gate dielectric layer comprises Ta₂O₅, and said second gate dielectric layer comprises Si₃N₄.

6. The transistor device of claim 1, wherein the first dielectric material disposed on the top and side surfaces of said gate metal is of a substantially uniform thickness.

7. A transistor device, comprising:
a flexible substrate;
patterned gate metal forming a gate and a portion of a gate line of the thin film transistor device;
a first gate dielectric layer comprising an anodized layer substantially covering only top and side surfaces of said gate metal, such that said first gate dielectric layer is minimally disposed over regions of said flexible substrate not also covered by said gate metal;
a second gate dielectric layer disposed substantially over a top surface of said first gate dielectric layer;
source and drain contacts disposed at least partially over said first gate dielectric;
a semiconductor material disposed at least between and in physical and electric contact with said source and drain contacts; and
said source and drain contacts and said semiconductor material are at least partially in physical contact with said second gate dielectric layer.

8. The transistor device of claim 7, wherein said semiconductor material comprises a semiconductive polymer.

9. The transistor device of claim 7, wherein said semiconductor material comprises amorphous silicon.

10. The transistor device of claim 7, wherein said gate metal is Ta and said first gate dielectric layer is Ta₂O₅.

11. The transistor device of claim 7, wherein said second gate dielectric layer is minimally disposed over regions of said flexible substrate not also covered by said first gate dielectric and said gate metal.

12. A method of forming a transistor device, comprising the steps of:
forming on a flexible substrate a pattered gate metal layer, the gate metal layer including at least a transistor gate and a portion of a gate line;
forming, by annodization, a first gate dielectric layer on the surface of the patterned gate metal layer, said first gate dielectric layer being minimally disposed over regions of said flexible substrate not also covered by said gate metal;
forming source and drain contacts at least partially over said first gate dielectric layer; and
forming a semiconductor region in physical and electric contact with said source and drain contacts, said semiconductor region comprising a polymer-based semiconductor material.

13. The method of forming a transistor device of claim 12, further comprising the steps of:
forming a second gate dielectric layer substantially over a top surface of said first gate dielectric layer.

14. The method of forming a transistor device of claim 13, wherein the step of forming a second gate dielectric layer comprises the steps of:
depositing substantially over the flexible substrate a continuous layer of dielectric material;
forming a mask over selected portions of said continuous layer of dielectric material, including over at least a portion of said first gate dielectric layer and a portion of said first gate dielectric layer;
removing portions of said continuous layer of dielectric material not covered by said mask; and
removing said mask;
whereby said second gate dielectric layer is minimally disposed over regions of said flexible substrate not also covered by said first gate dielectric and said gate metal.

15. The method of forming a transistor device of claim 12, wherein said gate metal is Ta and said first gate dielectric layer is Ta₂O₅.

16. A method of forming a transistor device, comprising the steps of:
forming on a flexible substrate a pattered gate metal layer, the gate metal layer including at least a transistor gate and a portion of a gate line;
forming, by annodization, a first gate dielectric layer on the surface of the patterned gate metal layer, said first gate dielectric layer being minimally disposed over regions of said flexible substrate not also covered by said gate metal;
forming a second gate dielectric layer disposed substantially over a top surface of said first gate dielectric layer, such that said second gate dielectric layer is minimally disposed over regions of said flexible substrate not also covered by said first gate dielectric and said gate metal; and
forming source and drain contacts at least partially over and in physical contact with said second gate dielectric layer, said source and drain contacts spaced apart from one another to form a semiconductor region.

17. The method of forming a transistor device of claim 16, wherein a polymer-based semiconductor material is deposited in said semiconductor region such that said polymer-based semiconductor material is in physical and electric contact with said source and drain contacts.

18. The method of forming a transistor device of claim 16, wherein an amorphous silicon semiconductor material is deposited in said semiconductor region such that said amorphous silicon semiconductor material is in physical and electric contact with said source and drain contacts.

19. The method of forming a transistor device of claim 16, wherein said gate metal is Ta and said first gate dielectric layer is Ta₂O₅.

20. A method of manufacturing a transistor device on a flexible substrate, comprising the steps of:
depositing on a flexible substrate a layer of gate metal;
patterning the layer of gate metal so as to form a gate structure of a semiconductor device;
anodizing the gate structure so as to form a first gate dielectric layer, substantially on the sides and top of the gate structure, which is thereby self-patterning with the gate structure; and
forming a second gate dielectric layer by a low-temperature process over the first gate dielectric layer such that the second gate dielectric layer is minimally disposed over regions of said flexible substrate not also covered by said first gate dielectric layer and said gate structure;
thereby providing a structure with minimized intrinsic stress.
